(19) United States
(12) Patent Application Publication
(10) Pub. No.: US 2005/0139917 A1
(43) Pub. Date: Jun. 30, 2005

(54) Semiconductor device

(76) Inventor: Yasushi Igarashi, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/848,170

(22) Filed: May 19, 2004

(30) Foreign Application Priority Data
Dec. 25, 2003 (JP) 2003-428613

(51) Int. Cl. H01L 27/12

(52) U.S. Cl. 257/347

(57) ABSTRACT

A semiconductor device has an anode impurity region and a cathode impurity region on a semiconductor substrate with a SOI (Silicon-On-Insulator) structure. An impurity region for voltage control is formed between the anode impurity region and the cathode impurity region.

### BACKGROUND OF THE INVENTION

1. Field of the Invention

The present invention relates to a semiconductor device, and in particular to a diode manufactured with an SOI (Silicon On Insulator) technology.

2. Description of the Related Art

By forming p-type and n-type impurity regions on a substrate of silicon or another semiconductor, a Zener diode can be used as a semiconductor device.

When a voltage (electric field) with a reverse bias is applied across the two terminals of the Zener diode, tunneling between bands occurs due to the Zener effect, and so the impedance across the terminals of the diode drops. The Zener effect occurs at or above a prescribed constant voltage, so that by utilizing this constant voltage, the voltage across the terminals of the Zener diode can be held constant. The constant voltage is determined, depending upon the types and concentrations of the impurities in the impurity regions.

A semiconductor substrate which is called an SOI substrate is known. In the SOI substrate, a silicon crystal thin film (silicon film) is formed on an oxide film. If a Zener diode is formed on the SOI substrate, the contact area of the p-type and n-type impurity regions provided on the silicon film is limited by the thickness dimension of the thin silicon film, so that the contact area is small. In other words, sufficient junction (interface) of the p-type and n-type impurity regions does not result. Therefore, the desired performance, namely, the desired constant voltage, cannot be obtained.

### SUMMARY OF THE INVENTION

One object of the present invention is to provide a semiconductor device for which the desired voltage value can be obtained.

According to a first aspect of the present invention, there is provided a semiconductor device which has an anode impurity region and a cathode impurity region on a semiconductor substrate. An impurity region for voltage control is formed between the anode impurity region and the cathode impurity region.

When a voltage is applied to the impurity region for voltage control, the channel electric field can be increased because the impurity region for voltage control is formed in the channel between the impurity region and cathode impurity region provided on the semiconductor substrate. Therefore, tunneling can be caused between the valence band and the conduction band. Hence, by controlling the voltage applied to the impurity region for voltage control which causes the increased electric field, and causing the tunneling between the bands, the breakdown voltage can be freely modified, so that a desired constant voltage can be easily obtained.

The impurity concentration in the impurity region for voltage control may be set lower than the impurity concentrations in the anode impurity region and in the cathode impurity region.

The impurity concentrations of the anode impurity region and the cathode impurity region may be set at from 1×10¹⁷/cm³ to 1×10²¹/cm³

The impurity concentration of the impurity region for voltage control may be set at from 1×10¹⁰/cm³ to 1×10¹⁸/cm³.

The impurity region for voltage control may be made common to a plurality of semiconductor devices.

According to a second aspect of the present invention, there is provided an improved voltage control circuit. A voltage applied to an input terminal of the voltage control circuit is controlled and output from an output terminal of the voltage control circuit. The voltage control circuit includes a semiconductor device. An anode of the semiconductor device is connected to a line connecting the input terminal of the voltage control circuit to the output terminal of the voltage control circuit. The semiconductor device has an anode impurity region and cathode impurity region formed in an SOI substrate. An impurity region for voltage control is provided between the anode impurity region and the cathode impurity region.

According to a third aspect of the present invention, there is provided an overvoltage protection circuit having an input terminal and an output terminal. The overvoltage protection circuit includes a resistance connected between the input and output terminals. The overvoltage protection circuit also includes two semiconductor devices connected to each other by respective cathodes. The anode of one semiconductor device is connected to the output terminal side of the resistance, and the anode of the other semiconductor device is grounded. In each semiconductor device, an anode impurity region and a cathode impurity region are formed on an SOI substrate, and an impurity region for voltage control is formed between the anode and cathode impurity regions. The overvoltage protection circuit also includes wiring for applying the voltage from the input terminal to each of the impurity regions for voltage control of the pair of semiconductor devices.

Other objects, aspects and advantages of the present invention will become apparent to those skilled in the art to which the present invention pertains from the following detailed description and appended claims when read and understood in conjunction with the accompanying drawings.

### BRIEF DESCRIPTION OF THE DRAWINGS

FIG. 1 is a cross-sectional view showing the structure of a semiconductor device according to one embodiment of the present invention;

FIG. 2A shows a wiring arrangement to apply a voltage to the semiconductor device shown in FIG. 1 for a forward-direction bias;

FIG. 2B shows another wiring arrangement to apply a voltage to the semiconductor device shown in FIG. 1 for a reverse-direction bias;

FIG. 3 shows the characteristics of the semiconductor device shown in FIG. 1;

FIG. 4A shows energy bands when a relatively low positive gate voltage is applied;

FIG. 4B shows energy bands when a relatively high positive gate voltage is applied;

FIG. 5A shows energy bands when a relatively low negative gate voltage is applied;

FIG. 5B shows energy bands when a relatively high negative gate voltage is applied;

FIG. 6 illustrates a voltage control circuit using a semiconductor device of the present invention; and,

FIG. 7 illustrates an overvoltage protection circuit using the semiconductor device of the present invention.

### DETAILED DESCRIPTION OF THE INVENTION

Below, embodiments of the present invention are described in detail using the drawings.

First Embodiment:

A semiconductor device of this embodiment is formed on a semiconductor substrate. This semiconductor substrate is an SOI substrate. In the SOI substrate, a thin film of silicon crystal (i.e., a semiconductor) is formed on an oxide film. The oxide film is an insulating film.

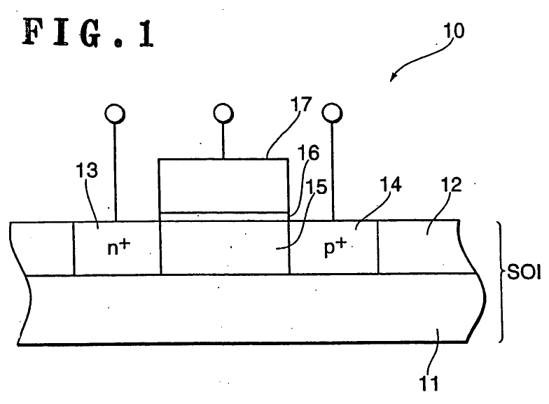

Referring to FIG. 1, a cross-sectional view of a semiconductor device 10 formed on such a semiconductor substrate is illustrated. The semiconductor device 10 includes, in the silicon film 12 on the oxide film 11, an n-type impurity region 13 for the anode (in the figure, denoted by “n+”), a p-type impurity region 14 for the cathode (in the figure, denoted by “p+”), an impurity region for voltage control 15 including impurities at a low concentration in the channel between the opposing n-type impurity region 13 and p-type impurity region 14, a gate oxide film 16 on the voltage-controlling impurity region 15, and a gate electrode 17 on the gate oxide film 16.

The silicon film 12 has a thickness sufficient to fully deplete. For example, the silicon film 12 has a thickness of 100 nm. The channel can be controlled through the gate.

The gate electrode 17 is polysilicon including for example phosphorus (P) at a concentration of 1×10⁹/cm³, and is formed to a thickness of for example 150 nm by chemical vapor deposition.

Wiring for application of voltage is connected to the gate electrode 17.

Electrodes, not shown, are formed on the n-type impurity region 13 and p-type impurity region 14, and wiring is connected to each of the electrodes.

The n-type impurity region 13 includes, for example, phosphorus (P), arsenic (As) or similar, as n-type impurities, at a concentration of 1×10¹⁷/cm³ to 1×10²¹/cm³. The p-type impurity region 14 includes, for example, boron (B), gallium (Ga) or similar, as p-type impurities, at a concentration of 1×10¹⁷/cm³ to 1×10²¹/cm³.

The voltage-controlling impurity region 15 includes either p-type or n-type impurities at a lower concentration than the impurity concentrations in the n-type impurity region 13 or p-type impurity region 14, that is, at an impurity concentration of ×10¹⁰/cm³ to 1×10¹⁸/cm³. In the following description, it should be assumed that the voltage-controlling impurity region 15 includes the p-type impurities.

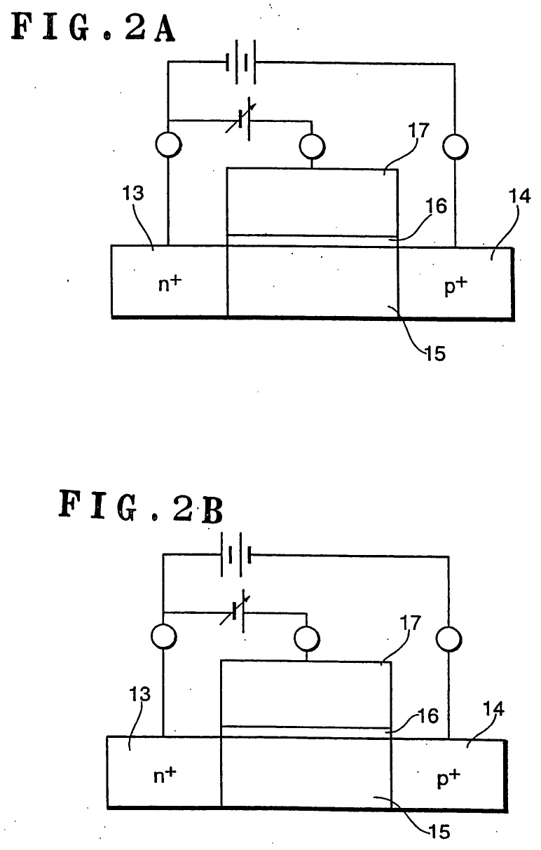

Next, a method of applying a voltage to the semiconductor device 10 is described using FIG. 2A and FIG. 2B.

FIG. 2A is a forward-bias connection diagram; a positive voltage is applied to the p-type impurity region 14, and a negative voltage is applied to the n-type impurity region 13. FIG. 2B is a reverse-bias connection diagram; a negative voltage is applied to the p-type impurity region 14, and a positive voltage is applied to the n-type impurity region 13.

A certain voltage (hereafter called the “gate voltage”) is applied to the gate electrode 17.

In the following description, it should be assumed that the impurity region for voltage control 15 is formed from a low-concentration p-type impurity.

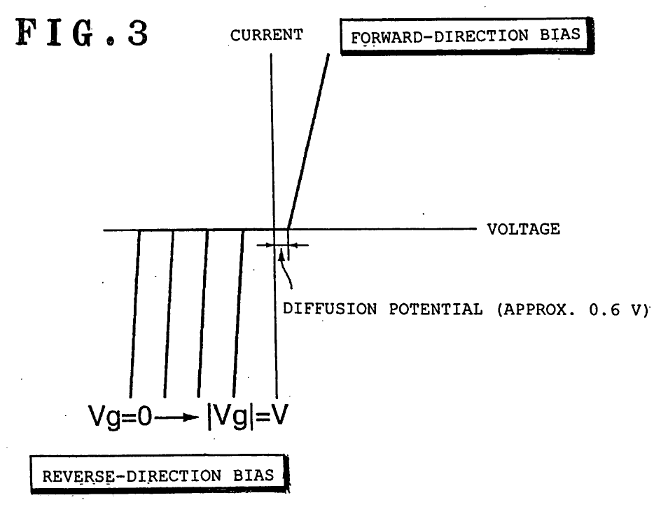

Referring to FIG. 3, characteristics of the semiconductor device 10 connected for forward-direction bias and reverse-direction bias are illustrated. The figure plots the current on the vertical axis and the voltage on the horizontal axis.

In the semiconductor device 10 connected for forward bias, when a positive voltage is applied to the p-type impurity region 14, holes in the p-type impurity region 14 move toward the n-type impurity region 13. When a negative voltage is applied to the n-type impurity region 13, electrons existing in the n-type impurity region 13 move toward the positive voltage element, that is, toward the electrode of the p-type impurity region 14. The holes from the p-type impurity region 14 and the electrons from the n-type impurity region 13 recombine in the voltage-controlling impurity region 15 because the voltage-controlling impurity region 15 is provided between the n-type impurity region 13 and the p-type impurity region 14.

This is similar to the forward bias of a diode at an ordinary pn junction. Hence, even if a voltage is applied to the gate electrode, there is little change in characteristics. That is, because the difference in energy levels in the p-type impurity region 14 and n-type impurity region 13 does not depend on the gate voltage, the characteristics change only to the extent that the position of recombination of electrons and holes changes. The change in recombination position occurs within the impurity region for voltage control 15 so that there is little possibility of resulting in an increase or decrease in current.

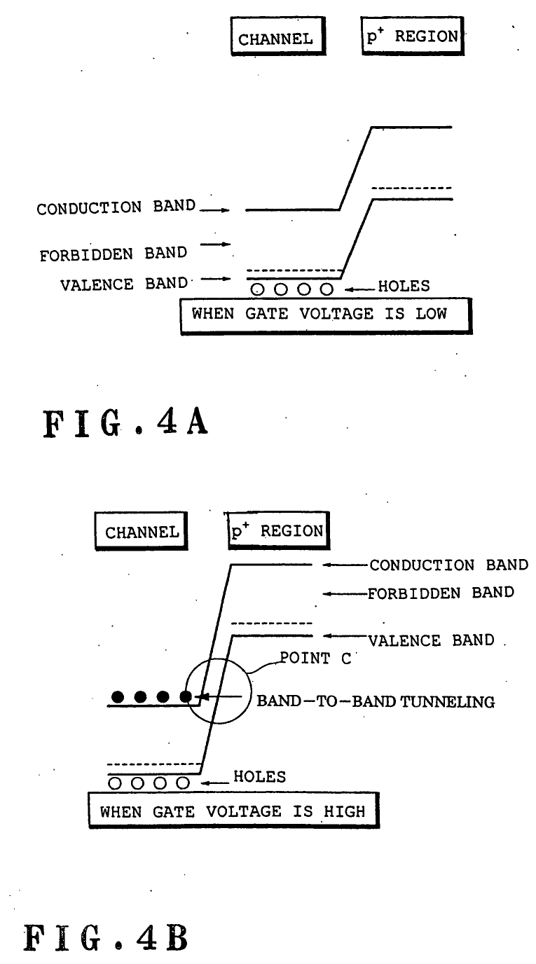

On the other hand, in the semiconductor device 10 connected with a reverse bias, when no gate voltage is applied, current does not flow until the breakdown voltage is reached. This is similarly to the reverse-bias characteristics of an ordinary. pn-junction diode. When, however, a negative gate voltage is applied to the gate electrode, the hole concentration rises in the channel, that is, in the voltage-controlling impurity region 15 on the side of the gate oxide film 16, and a strong electric field occurs in the voltage-controlling impurity region 15 near the p-type impurity region 14. This strong electric field creates a so-called band-to-band tunneling, as shown in FIG. 4B. In the band-to-band tunneling, electrons tunnel from the valence band to the conduction band through the forbidden band. As a result, the value of the breakdown voltage can be modified in accordance with the value of the gate voltage.

FIG. 4A is an energy band diagram when a low gate voltage is applied, and FIG. 4B is an energy band diagram when a high gate voltage is applied. As shown in FIG. 4B, when a high negative voltage is applied to the gate electrode, the energy levels of the valence band and conduction band in the channel are lowered, and the valence band in the p-type impurity region 14 and conduction band in the channel approach the point c in FIG. 4B. Therefore, the forbidden band between the valence band of the p-type impurity region 14 and the conduction band of the channel is narrowed, and tunneling between the bands occurs readily. As a result, electrons in the p-type impurity region 14 can easily move from the p-type impurity region 14 to the voltage-controlling impurity region 15.

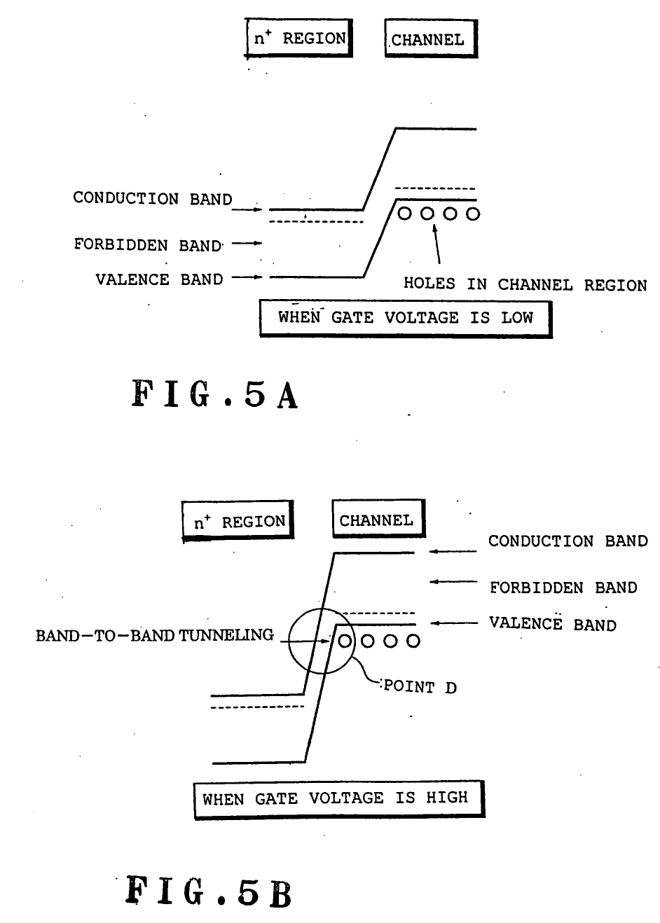

When a positive gate voltage is applied to the gate electrode, the energy levels in the voltage-controlling impurity region 15 rise, and a strong electric field appears near the n-type impurity region 13. Due to this strong electric field, as shown in FIG. 5B, holes tunnel from the conduction band of the n-type impurity region 13 to the valence band of the channel, and so-called band-to-band tunneling occurs, so that the value of the breakdown voltage can be modified according to the value of the gate voltage.

FIG. 5A is an energy band diagram when a low gate voltage is applied, and FIG. 5B is an energy band diagram when a high positive gate voltage is applied. As depicted in FIG. 5B, when a high positive voltage is applied to the gate electrode, the energy levels of the channel valence band and conduction band rise, and the channel valence band and the conduction band of the n-type impurity region 13 approach the point d in FIG. 5B. Therefore, the forbidden band between the valence band and conduction band is narrowed, and the band-to-band tunneling occurs readily. Hence, when a high voltage is applied to the gate electrode, holes easily move from the n-type impurity region 13 to the impurity region for voltage control 15.

The state of band-to-band tunneling changes with the electric field intensity in the voltage-controlling impurity region 15. That is, as shown in FIG. 3, when the voltage applied to the gate electrode 17 of the semiconductor device 10 connected for reverse bias is gradually increased, the breakdown voltage rises. Since the semiconductor device 10 of this first embodiment has the gate electrode 17 on the SOI semiconductor substrate, the gate voltage can be applied to the voltage-controlling impurity region 15 via the gate electrode 17. Because a strong electric field arises and band-to-band tunneling occurs according to the gate voltage value, the breakdown voltage can be controlled through the gate voltage.

In the case of a voltage controlling element which uses a pn junction, the smallest voltage is obtained when the forward-bias diffusion potential is utilized. That is, normally a voltage of approximately 0.6 V is obtained. Hence, when a conventional voltage controlling element is used, voltage control at values equal to or above the diffusion potential is possible.

On the other hand, in the semiconductor device 10 of the present invention the gate voltage is controlled to cause changes in the energy levels of the energy bands in the voltage-controlling impurity region 15. Hence using the semiconductor device 10, voltage control is possible even at values equal to or below the diffusion potential, that is, at 0.6 V or below.

As described above, the voltage-controlling impurity region 15 in the first embodiment may be formed using n-type impurities at a low concentration. Alternatively, the voltage-controlling impurity region 15 may be formed using p-type impurities.

Second Embodiment:

Next, a voltage control circuit which uses the semiconductor device 10 of the first embodiment is described.

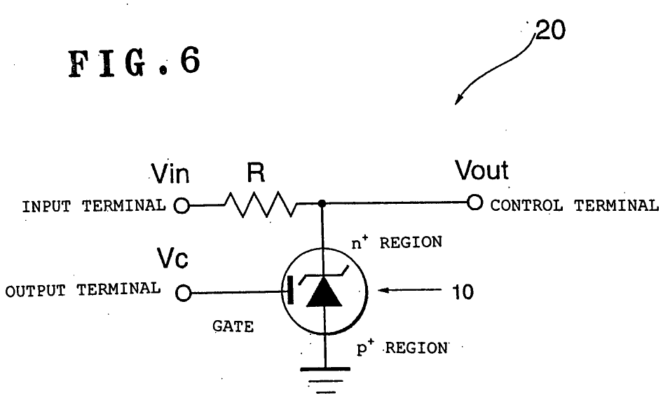

As shown in FIG. 6, the voltage control circuit 20 has an input terminal, an output terminal, a resistance R provided between the input terminal and output terminal. The voltage control circuit 20 also includes the semiconductor device 10, with its anode connected to the resistance R on the output terminal side, that is, connected for a reverse bias. The voltage control circuit 20 also includes a control terminal connected to the gate electrode of the semiconductor device 10. The cathode of the semiconductor device 10 is grounded.

The resistance R is a protective resistance for the semiconductor device 10. Specifically, when the resistance value of the semiconductor device 10 is small, power is consumed by the resistance R.

In the following description, the voltage applied to the input terminal is denoted by Vᵢₙ, the voltage at the output terminal is denoted by Vₒᵤₜ, and the voltage applied to the control terminal is denoted by V_{c}.

When the voltage V_{c} is applied to the control terminal of the voltage control circuit 20, the voltage across the anode and cathode of the semiconductor device 10 is controlled (adjusted). Under the influence of this voltage control, the Vᵢₙ applied to the input terminal of the voltage control circuit 20 is adjusted to the output voltage Vₒᵤₜ.

As a result, the voltage control circuit 20 can change an input voltage value to a desired voltage value for output, by controlling the voltage V_{c}.

Third Embodiment:

Next, an overvoltage protection circuit 30 using two semiconductor devices (denoted by 21 and 22) of the first embodiment is described. Each of the two semiconductor devices has substantially the same configuration as the semiconductor device 10 shown in FIG. 1.

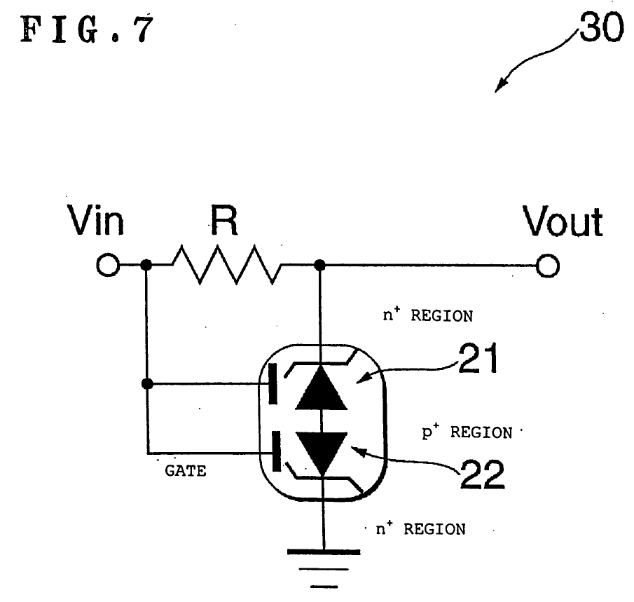

Referring to FIG. 7, the overvoltage protection circuit 30 includes an input terminal, an output terminal, a resistance R provided between the input and output terminals, and a pair of semiconductor devices 21 and 22. The anode of the first semiconductor device 21 is connected to the resistance R on the side of the output terminal. The cathode of the first semiconductor device 21 is connected to the cathode of the second semiconductor device 22. The anode of the second semiconductor device 22 is grounded. Both the gate electrodes of the first semiconductor device 21 and second semiconductor device 22 are connected to the input terminal by wiring for application of the voltage from the input terminal.

The p-type impurity region 14 of the first semiconductor device 21, as the cathode, is electrically connected to the p-type impurity region 14 of the second semiconductor device 22, as the cathode, by wiring. It should be noted that a single p-type impurity region 14 may be shared by the first and second semiconductor devices 21 and 22.

In this embodiment, a pair of semiconductor devices 21 and 22 are used in order to enable operation for both positive voltages and negative voltages.

When the voltage Vᵢₙ equal to or exceeding the tolerance value is input to the overvoltage protection circuit 30 from an input/output terminal, called a pad of an IC or similar, the resistance values of the semiconductor device 21 and semiconductor device 22 become small, and therefore the voltage from the pad can be grounded through the resistance R.

The present invention is not limited to the illustrated and described embodiments. For example, although the cathode (i.e., the p-type impurity region 14) of the first semiconductor device 21 is coupled to the cathode (i.e., the p-type impurity region 14) of the second semiconductor device 22 in the third embodiment, the anode (i.e., the n-type impurity region 13) of the first semiconductor device 21 may be coupled with the anode (i.e., the n-type impurity region 13) of the second semiconductor device 22.

Although the semiconductor device 10 is formed on the fully-depleted SOI-semiconductor substrate, it may be formed on a partially-depleted semiconductor substrate.

This application is based on a Japanese Patent Application No. 2003-428613 filed on Dec. 5, 2003, and the entire disclosure thereof is incorporated herein by reference.

1. A semiconductor device comprising:
a substrate with an SOI (Silicon-On-Insulator) structure;
an anode impurity region formed on the substrate;
a cathode impurity region on the substrate; and
an impurity region for voltage control, formed between the anode impurity region and the cathode impurity region.

2. The semiconductor device according to claim 1, wherein an impurity concentration of the impurity region for voltage control is lower than an impurity concentration in the anode impurity region and lower than an impurity concentration in the cathode impurity region.

3. The semiconductor device according to claim 2, wherein the impurity concentrations in the anode impurity region and in the cathode impurity region are from 1×10¹⁷/cm³ to 1×10²¹/cm³.

4. The semiconductor device according to claim 2, wherein the impurity concentration in the impurity region for voltage control is from 1×10¹⁰/cm³ to 1×10¹⁸/cm³.

5. The semiconductor device according to claim 1, wherein the impurity region for voltage control is common to a plurality of semiconductor devices.

6. A voltage control circuit for controlling an input voltage supplied to the voltage circuit so as to output a controlled voltage, comprising:
an input terminal to which the input voltage is applied;
an output terminal from which the controlled voltage is output;
a line connecting the input terminal to the output terminal; and
a semiconductor device having a substrate with an SOI structure, an anode impurity region on the substrate, a cathode impurity region on the substrate, and a voltage-controlling impurity region between the anode and cathode impurity regions, an anode of the semiconductor device being connected the line between the input and output terminals.

7. The voltage control circuit according to claim 6 further comprising wiring for applying a control voltage to the voltage-controlling impurity region of the semiconductor device to control a voltage across the anode and cathode of the semiconductor device.

8. The voltage control circuit according to claim 6 further including a resistance on the line, the anode of the semiconductor device being connected to the line between the resistance and the output terminal.

9. The voltage control circuit according to claim 6, wherein a cathode of the semiconductor device is grounded.

10. The voltage control circuit according to claim 6, wherein an impurity concentration of the impurity region for voltage control is lower than an impurity concentration in the anode impurity region and lower than an impurity concentration in the cathode impurity region.

11. The voltage control circuit according to claim 10, wherein the impurity concentrations in the anode impurity region and in the cathode impurity region are from 1×10¹⁷/cm³ to 1×10²¹/cm³.

12. The voltage control circuit according to claim 10, wherein the impurity concentration in the impurity region for voltage control is from 1×10¹⁰/cm³ to 1×18¹⁸/cm³.

13. An overvoltage protection circuit comprising:
an input terminal;
an output terminal;
a line connecting the input terminal to the output terminal;
a resistance provided on the line;
first and second semiconductor devices connected to each other, each of the first and second semiconductor devices having a substrate with an SOI structure, a cathode impurity region on the substrate, an anode impurity region on the substrate, and a voltage-controlling impurity region between the anode and cathode impurity regions, a cathode of the first semiconductor device being connected to a cathode of the second semiconductor device, an anode of the first semiconductor device being connected to the line between the output terminal and the resistance, and an anode of the second semiconductor devices being grounded; and
wiring extending from the input terminal to the first and second semiconductor devices to apply a voltage from the input terminal to the voltage-controlling impurity regions of the first and second semiconductor devices.

14. The overvoltage protection circuit according to claim 13, wherein an impurity concentration of the impurity region for voltage control is lower than an impurity concentration in the anode impurity region and lower than an impurity concentration in the cathode impurity region.

15. The overvoltage protection circuit according to claim 14, wherein the impurity concentrations in the anode impurity region and in the cathode impurity region are from 1×10¹⁷/cm³ to 1×10²¹/cm³.

16. The overvoltage protection circuit according to claim 14, wherein the impurity concentration in the impurity region for voltage control is from 1×10¹⁰/cm³ to 1×10¹⁸/cm³.

17. The overvoltage protection circuit according to claim 13, wherein a single cathode impurity region is shared by the first and second semiconductor devices.

18. An overvoltage protection circuit comprising:
an input terminal;
an output terminal;
a line connecting the input terminal to the output terminal;
a resistance provided on the line;
first and second semiconductor devices connected to each other, each of the first and second semiconductor devices having a substrate with an SOI structure, a cathode impurity region on the substrate, an anode impurity region on the substrate, and a voltage-controlling impurity region between the anode and cathode impurity regions, an anode of the first semiconductor device being connected to an anode of the second semiconductor device, a cathode of the first semiconductor device being connected to the line between the output terminal and the resistance, and a cathode of the second semiconductor devices being grounded; and
wiring extending from the input terminal to the first and second semiconductor devices to apply a voltage from the input terminal to the voltage-controlling impurity regions of the first and second semiconductor devices.

19. The overvoltage protection circuit according to claim 18, wherein an impurity concentration of the impurity region for voltage control is lower than an impurity concentration in the anode impurity region and lower than an impurity concentration in the cathode impurity region.

20. The overvoltage protection circuit according to claim 19, wherein the impurity concentrations in the anode impurity region and in the cathode impurity region are from 1×10¹⁷/cm³ to 1×10²¹/cm³.

21. The overvoltage protection circuit according to claim 19, wherein the impurity concentration in the impurity region for voltage control is from 1×10¹⁰/cm³ to 1×10¹⁸/cm³.

22. The overvoltage protection circuit according to claim 18, wherein a single anode impurity region is shared by the first and second semiconductor devices.
